(19) United States
(12) Patent Application Publication
(10) Pub. No.: US 2008/0145975 A1
(43) Pub. Date: Jun. 19, 2008

(54) METHOD FOR FABRICATING CIRCUIT BOARD STRUCTURE WITH EMBEDDED SEMICONDUCTOR CHIP

(75) Inventors: Shih-Ping Hsu, Hsin-Chu (TW); Shang-Wei Chen, Hsinchu (TW)

Correspondence Address: SCHMEISER OLSEN & WATTS, 18 E UNIVERSITY DRIVE, SUITE # 101, MESA, AZ, 85201, US

(73) Assignee: Phoenix Precision Technology Corporation, Hsin-Chu (TW)

(21) Appl. No.: 11/956,258

(22) Filed: Dec. 13, 2007

(30) Foreign Application Priority Data
Dec. 15, 2006 (TW) 095147083

(51) Int. Cl. H01L 21/58

(52) U.S. Cl. 438/123; 257/E23.142

(57) ABSTRACT

The invention provides a method for fabricating printed circuit board having an embedded semiconductor chip, including: providing a carrier board including a first and a second surface and at least one through hole penetrating the first and second surfaces; disposing a semiconductor chip in the through hole and including an active surface and an inactive surface, the active surface including a plurality of electrode pads; forming at least one non photoimagable laminating layer on the first surface of the carrier board with a through hole to expose the inactive surface of the semiconductor chip; forming a dielectric layer on the second surface of the carrier board and the active surface of the semiconductor chip; and forming a circuit layer on the dielectric layer, the circuit layer electrically connecting to the electrode pads of the semiconductor chip through conductive structures in the dielectric layer, thereby preventing the carrier board from warpage due to temperature variations and an asymmetric structure during a single-side circuit formation process of the carrier board.

### FIELD OF THE INVENTION

The present invention relates to a method for fabricating circuit board structure, and more particularly, to a method for fabricating circuit board structure embedded with a semiconductor chip.

### BACKGROUND OF THE INVENTION

Various types of packaging for semiconductor devices have been developed along with the evolution of semiconductor packaging technique. Packaging mainly involves installing a semiconductor chip on a package substrate or a lead frame, then electrically connecting the semiconductor chip to the package substrate or the lead frame, and encapsulating the semiconductor chip using an encapsulation material. Ball Grid Array (BGA) is one of the advanced semiconductor packaging techniques that employs a package substrate for disposing the semiconductor chip. A plurality of solder balls in the form of grid array for connection with external devices is formed at the backside of package substrate, so as to accommodate more I/O connections on the carrier surface of the package substrate to conductive to the high integration semiconductor chip.

In a traditional package structure, the semiconductor is adhered to the top surface of the substrate, and wiring bonding or flip chip packaging is performed before the solder balls are implanted to the backside of the substrate for electrical connection. It allows high pin counts, but creates a problem during high frequency application or high speed operations. The problem is that the impedance tends to be large due to long lead paths, this deteriorates electrical performance. Additionally, traditional packaging requires more connecting interfaces, which increases fabricating cost.

In order to solve this problem, the semiconductor chip is embedded into a carrier board for direct electrical connection to reduce electrical propagation paths, as well as reducing signal loss and distortion and increasing performance during high speed operations.

FIG. 1 is a cross-sectional schematic diagram of a circuit board structure, wherein a semiconductor chip is embedded in a carrier board. The structure includes a carrier board 10 having a first surface 101 and a second surface 102 opposite to the first surface; At least one through hole 100 penetrates the first and second surfaces, wherein a semiconductor chip 11 is disposed via some adhesive material 110. The semiconductor chip 11 has an active surface 11a and an inactive surface 11b opposite to the active surface 11a. A plurality of electrode pads 111 is formed on the active surface 11a. A circuit build up structure 12 is formed on the first surface 101 of the carrier board 10 and the active surface 11a of the semiconductor chip 11. The circuit build up structure 12 includes a dielectric layer 120, a circuit layer 121 overlying the dielectric layer 120 and conductive vias 122 formed in the dielectric layer 120. The conductive vias 122 are electrically connected to the electrode pads 111 of the semiconductor chip 11.

The chip-embedded circuit board structure solves the abovementioned problem, but it requires forming the circuit build up structure 12 on the first surface 101 of the carrier board 10. Since build up is performed on only one side, the circuit board structure is asymmetric, which causes uneven thermal stress when temperature varies during various manufacturing processes, such as baking or thermal cycling. Thermal stress may result in substrate warpage, delamination or even chip cracking.

Therefore, there is a need for a chip-embedded circuit board structure that eliminates warpage during manufacturing processes of the circuit board structure and reduces cost.

### SUMMARY OF THE INVENTION

In the light of forgoing drawbacks, an objective of the present invention is to provide a method for fabricating circuit board structure with an embedded semiconductor chip to eliminate warpage in the packaging structure during thermal processes.

Another objective of the present invention is to provide a method for fabricating circuit board structure with an embedded semiconductor chip to avoid chip damage caused by warpage of circuit board structure.

In accordance with the above and other objectives, the present invention provides a method for fabricating circuit board structure with an embedded semiconductor chip, including: providing a carrier board including a first and a second surface and at least one through hole penetrating the first and second surfaces; disposing a semiconductor chip in the through hole and including an active surface and an inactive surface, the active surface including a plurality of electrode pads; forming at least one non photoimagable laminating layer on the first surface of the carrier board with a through hole to expose the inactive surface of the semiconductor chip; forming a dielectric layer on the second surface of the carrier board and the active surface of the semiconductor chip; and forming a circuit layer on the dielectric layer, the circuit layer electrically connecting to the electrode pads of the semiconductor chip through conductive structures in the dielectric layer.

The above method further includes forming a circuit build up structure on the surface of the dielectric layer and circuit layer. The circuit build up structure includes a dielectric layer, a circuit layer overlying on the surface of the dielectric layer and at least one conductive structure formed in the dielectric layer. The above method further includes forming a plurality of electrically connecting pads on the outer surface of the circuit build up structure. A solder mask is further covered on the outer surface of the circuit build up structure with a plurality of openings for exposing the electrically connecting pads on the outer surface of the circuit build up structure. Conductive elements, such as solder balls, metal pins or metal lands, are formed on the surface of these electrically connecting pads.

The carrier board can be an insulating board, a metal board or a circuit board thereon; or composed of at least two core plates and an interposed adhesive layer. The adhesive layer is filled into the gaps between the through hole of the carrier board and the semiconductor chip, so as to secure the semiconductor chip in the through hole. The core plates can be insulating plates, a metal plates or circuit boards thereon. Additionally, the method of the present invention may include forming the dielectric layers and circuit layers on the second surface of the carrier board and on the active face of the semiconductor chip before forming the laminating layers on the first surface of the carrier board, or forming the laminating layers on the first surface of the carrier board before forming the dielectric layers and circuit layers on the second surface of the carrier board and on the active face of the semiconductor chip.

In an embodiment of the present invention, the carrier board includes at least two core plates and an interposed adhesive layer, the adhesive layer being filled into the gaps between the through hole of the carrier board and the semiconductor chip, so as to secure the semiconductor chip in the through hole.

Moreover, in the present invention, the number of the laminating layer is adjusted based on the number of the circuit build up structure, forming at least one laminating layer on the first surface of the carrier board, so as to avoid warpage of the circuit board structure.

Therefore, the method for fabricating circuit board structure with an embedded semiconductor chip of the present invention essentially forms a laminating layer on the first surface of the carrier board while performing the circuit formation process on the second surface of the carrier board, so as to balance the thermal stress in the packaging structure due to temperature variation in the circuit formation process and control warpage occurred as a result of temperature variation in the fabrication process, thereby preventing the semiconductor chip from damage.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional schematic diagram of a traditional embedded-type packaging structure;

FIGS. 2A to 2F are cross-sectional diagrams illustrating a first embodiment of a method for fabricating a circuit board structure with an embedded semiconductor chip of the present invention; and

FIGS. 3A to 3D are cross-sectional diagrams illustrating a second embodiment of the method for fabricating a circuit board structure with an embedded semiconductor chip of the present invention.

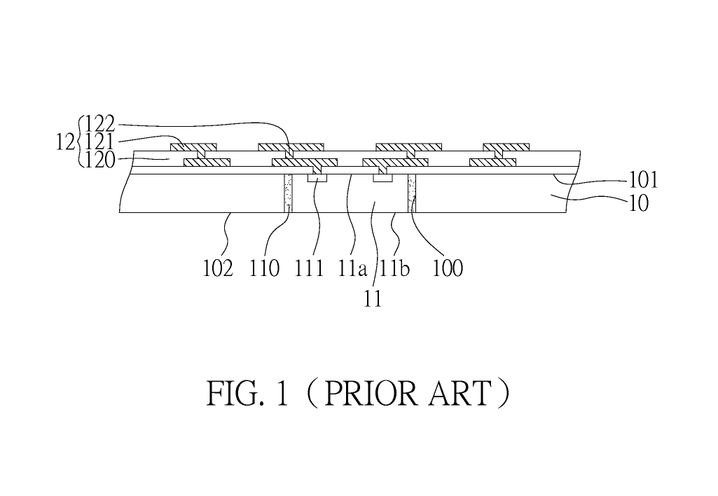

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

### First Embodiment

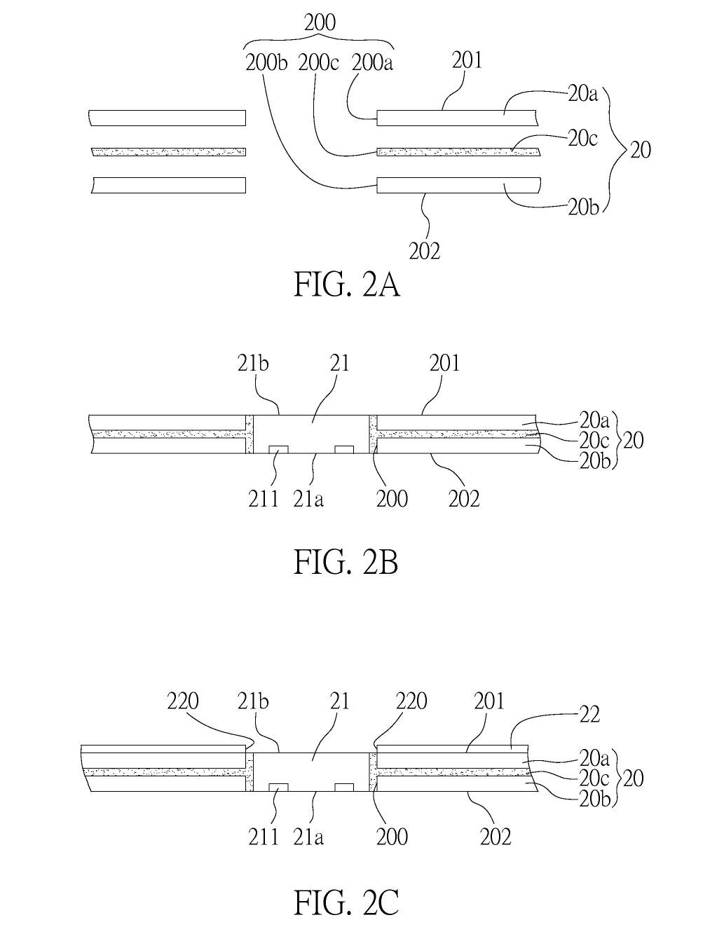

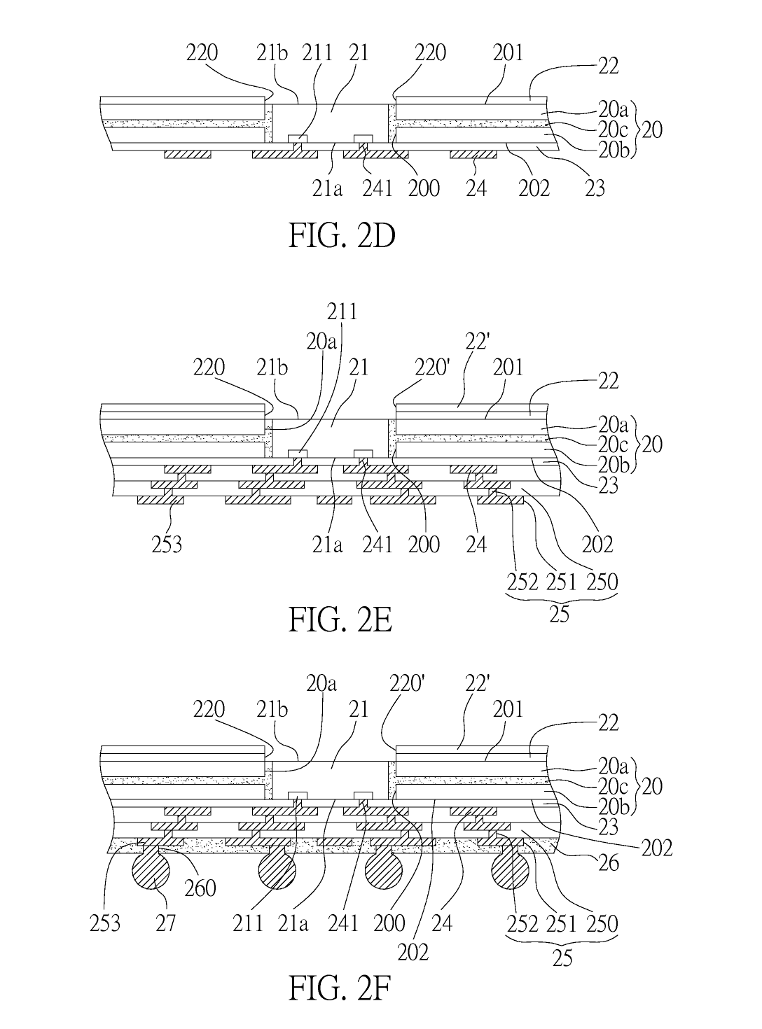

Referring to FIGS. 2A to 2F, which are cross-sectional diagrams illustrating a method for fabricating a circuit board structure with an embedded semiconductor chip of the present invention.

As shown in FIG. 2A, a carrier board 20 with a first surface 201 and a second surface 202 is provided. The carrier board 20 is a circuit board, insulating plate or metal plate thereon. At least two core plates 20a and 20b and an adhesive layer are provided. Through holes 200a, 200b, and 200c are formed on the core plates 20a and 20b and an adhesive layer 20c, respectively. The adhesive layer 20c is interposed between the core plates 20a and 20b, such that at least one through hole 200 is formed in the carrier board 20 penetrating through the core plates 20a and 20b and the adhesive layer 20c. The outer surfaces of the core plates 20a and 20b are the first surface 201 and the second surface 202 of the carrier board 20, respectively. The core plates 20a and 20b may be circuit boards, insulating plates or metal plates thereon.

As shown in FIG. 2B, a semiconductor chip 21 is disposed in the through hole 200 of the carrier board 20. The semiconductor chip 21 has an active face 21a and an inactive face 21b opposing the active face 21a. The active face 21a of the semiconductor chip 21 is on the same side as the second surface 202 of the carrier board 20. The active face 21a has a plurality of electrode pads 211. Then, the carrier board 20 is laminated and the adhesive layer 20c is filled in the gaps between the through hole 200 and the semiconductor chip 21, so as to secure the semiconductor chip 21 in the through hole 200.

As shown in FIG. 2C, a laminating layer 22 is formed on the first surface 201 of the carrier board 20. A through hole 220 is formed in the laminating layer 22 that exposes the inactive face 21b of the semiconductor chip 21. The material of the laminating layer 22 can be non photoimagable material such as flow prepreg, non-flow prepreg, resin coated copper (RCC), Ajinomoto Build up Film, BCB (Benzocyclo-buthene), LCP (Liquid Crystal Polymer), PI (Poly-imide), PPE (Poly(phenylene ether)), PTFE (Poly(tetra-fluoroethylene)), FR4, FR5, BT (Bismaleimide Triazine) or Aramide.

As shown in FIG. 2D, a dielectric layer 23 is formed on the second surface 202 of the carrier board 20 and the active face 21a of the semiconductor chip 21. Then, a circuit layer 24 is formed on the surface of the dielectric layer 23, wherein the circuit layer 24 electrically connects with the electrode pads 211 of the semiconductor chip 21 via the conductive structures 241 of the dielectric layer 23.

As shown in FIG. 2E, a circuit build up structure 25 is formed on the dielectric layer 23 and the circuit layer 24 by carrying out circuit build up fabricating process. The circuit build up structure 25 includes a dielectric layer 250, a circuit layer 251 overlying the dielectric layer 250 and conductive structures 252 formed in the dielectric layer 250. A plurality of electrically connecting pads 253 is formed on the outer surface of the circuit build up structure 25.

In this embodiment, during the circuit build up fabricating process, if the packaging structure bends towards the side of the build up layer due to temperature variation, an additional laminating layer 22′ can be laminated onto the first surface 201 of the carrier board 20, such that a plurality of laminating layers 22 and 22′ are formed on the surface of the carrier board 20. Through holes 220 and 220′ are formed in the laminating layers 22 and 22′ to expose the inactive face 21b of the semiconductor chip 21. These laminating layers 22 and 22′ eliminate warpage due to temperature-varying processes. Thus, in this embodiment, the number of laminating layer 22 on the first surface 201 of the carrier board 20 is adjusted based on the number of build up layers 25 on the second surface 202 and the active face 21a of the semiconductor chip 21, so as to compensate warpage caused by uneven single-side lamination.

As shown in FIG. 2F, an insulating protection layer 26 is covered on the outer surface of the circuit build up layer 25, wherein a plurality of openings 260 is formed to expose the electrical connecting pads 253 on the outer surface of the circuit build up layer 25. Conductive elements 27, such as solder balls, metal pins or metal lands, are formed on the surface of these electrically connecting pads 253 for electrically connecting the semiconductor chip 21 embedded in the carrier board 20 to other external electrical devices.

Alternatively, in the method for fabricating the circuit board structure with an embedded semiconductor chip, instead of forming the laminating layers on the first surface of the carrier board before forming the dielectric layers and circuit layers on the second surface of the carrier board and on the active face of the semiconductor chip, the dielectric layers and circuit layers can be formed on the second surface of the carrier board and on the active face of the semiconductor chip before forming the laminating layers on the first surface of the carrier board.

According to the above method, the present invention further provides a circuit board structure with an embedded semiconductor chip, which includes: a carrier board 20 including at least two core plates 20a and 20b and an adhesive layer 20c therebetween, the core plates 20a and 20b and the adhesive layer 20c having through holes 200a, 200b and 200c, respectively, so as to form at least one through hole 200 in the carrier board 20 penetrating through the core plates 20a and 20b and the adhesive layer 20c, the outer surfaces of the core plates 20a and 20b being the first surface 201 and the second surface 202 of the carrier board 20, respectively; a semiconductor chip 21 disposed in the through hole 200 having an active face 21a with a plurality of electrode pads and an inactive face 21b opposing the active face 21a; a laminating layer 22 formed on the first surface 201 of the carrier board 20 having a through hole 220 for exposing the inactive face 21b of the semiconductor chip 21; a dielectric layer 23 formed on the second surface 202 of the carrier board 20 and the surface of the semiconductor chip 21; and a circuit layer 24 formed on the dielectric layer 23, the circuit layer 24 electrically connecting to the electrode pads 211 of the semiconductor chip 21 via conductive structures 241 formed in the dielectric layer 23.

A circuit build up structure 25 is further formed on the surface of the dielectric layer 23 and the circuit layer 24, while at least another laminating layer 22′ is further laminated to the laminating layer 22. Through holes 220 and 220′ are formed in the laminating layers 22 and 22′ for exposing the inactive face 21b of the semiconductor chip 21.

The circuit build up structure 25 includes a dielectric layer 250, a circuit layer 251 overlying the dielectric layer 250 and conductive structures 252 formed in the dielectric layer 250. A plurality of electrically connecting pads 253 is formed on the outer surface of the circuit build up structure 25. An insulating protection layer 26 is covered on the outer surface of the circuit build up layer 25, wherein a plurality of openings 260 is formed to expose the electrical connecting pads 253 on the outer surface of the circuit build up layer 25. Conductive elements 27, such as solder balls, metal pins or metal lands, are formed on the surface of these electrically connecting pads 253 for electrically connecting the semiconductor chip 21 embedded in the carrier board 20 to other external electrical devices.

### Second Embodiment

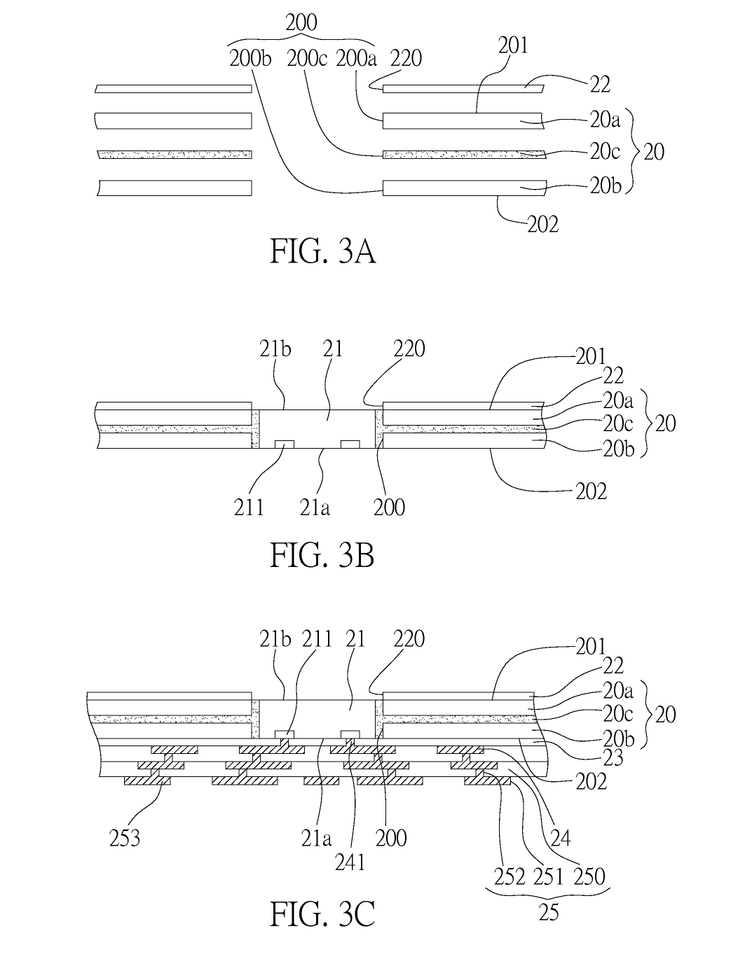

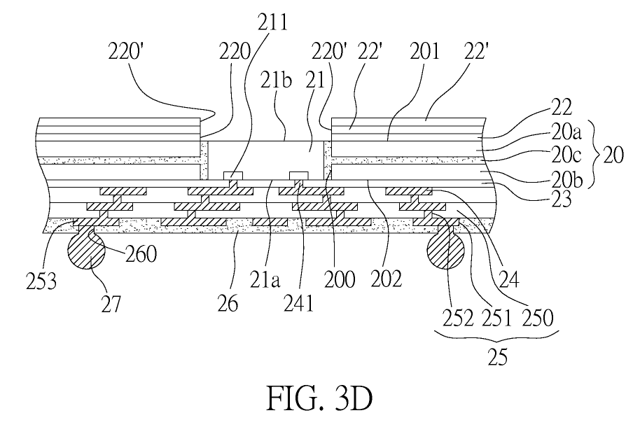

Referring to FIGS. 3A to 3D, which are cross-sectional diagrams illustrating a second embodiment of the method for fabricating a circuit board structure with an embedded semiconductor chip according to the present invention. This is different from the first embodiment in that a laminating layer is first laminated to the first surface of the carrier board before forming a dielectric layer and a circuit layer on the second surface of the carrier board.

As shown in FIG. 3A, a carrier board 20 is provided, which can be a circuit board, insulating plate or metal plate thereon; or including at least two core plates 20a and 20b and an adhesive layer 20c. Through holes 200a, 200b, and 200c are formed on the core plates 20a and 20b and an adhesive layer 20c, respectively. The adhesive layer 20c is interposed between the core plates 20a and 20b, such that at least one through hole 200 is formed in the carrier board 20 penetrating through the core plates 20a and 20b and the adhesive layer 20c. The outer surface of the core plate 20a is the first surface 201 of the carrier board 20, and the outer surface of the core plate 20b is the second surface 202 of the carrier board 20. A laminating layer 22 is formed on a first surface 201 of the carrier board 20 having a through hole 220 corresponding to the through hole 200 of the carrier board.

As shown in FIG. 3B, a semiconductor chip 21 is disposed in the through hole 200 of the carrier board 20. The semiconductor chip 21 has an active face 21a and an inactive face 21b opposing the active face 21a. The active face 21a of the semiconductor chip 21 is on the same side as the second surface 202 of the carrier board 20. The active face 21a has a plurality of electrode pads 211. Then, the carrier board 20 is laminated and the adhesive layer 20c is filled in the gaps between the through hole 200 and the semiconductor chip 21, so as to secure the semiconductor chip 21 in the through hole 200.

As shown in FIG. 3C, a dielectric layer 23 is formed on the second surface 202 of the carrier board 20 and the active face 21a of the semiconductor chip 21. Then, a circuit layer 24 is formed on the surface of the dielectric layer 23, wherein the circuit layer 24 electrically connects with the electrode pads 211 of the semiconductor chip 21 via the conductive structures 241 of the dielectric layer 23. A circuit build up structure 25 is formed on the dielectric layer 23 and the circuit layer 24. The circuit build up structure 25 includes a dielectric layer 250, a circuit layer 251 overlying the dielectric layer 250 and conductive structures 252 formed in the dielectric layer 250. A plurality of electrically connecting pads 253 is formed on the outer surface of the circuit build up structure 25.

In this embodiment as shown in FIG. 3D, depending on actual circumstances, at least a laminating layer 22′ can be further laminated onto the first surface 201 of the carrier board 20, such that a plurality of laminating layers 22 and 22′ are formed on the surface of the carrier board 20. Through holes 220 and 220′ are formed in the laminating layers 22 and 22′ to expose the inactive face 21b of the semiconductor chip 21. These laminating layers 22 and 22′ eliminate warpage due to temperature-varying processes.

Additionally, an insulating protection layer 26 is covered on the outer surface of the circuit build up layer 25, wherein a plurality of openings 260 is formed to expose the electrical connecting pads 253 on the outer surface of the circuit build up layer 25. Conductive elements 27, such as solder balls, metal pins or metal lands, are formed on the surface of these electrically connecting pads 253 for electrically connecting the semiconductor chip 21 embedded in the carrier board 20 to other external electrical devices.

Alternatively, in this embodiment, instead of forming the dielectric layers and circuit layers on the second surface of the carrier board and on the active face of the semiconductor chip before forming the laminating layers on the first surface of the carrier board, the laminating layers can be formed on the first surface of the carrier board before forming the dielectric layers and circuit layers on the second surface of the carrier board and on the active face of the semiconductor chip.

The circuit board structure with an embedded semiconductor chip essentially forms a laminating layer for balance on the first surface of the carrier board while performing the circuit formation process on the second surface of the carrier board, so as to balance the thermal stress in the packaging structure due to temperature variation in the circuit formation process. Additionally, in the circuit build up process, a laminating layer for balance can be laminated on the first surface of the carrier board so as to form at least one laminating layer on the first surface of the carrier board, so as to control warpage occurred as a result of temperature variation in the fabrication process, thereby preventing the semiconductor chip from damage.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A method for fabricating a circuit board structure with an embedded semiconductor chip, including:
providing a carrier board including a first and a second surface and at least one through hole penetrating the first and second surfaces;
disposing a semiconductor chip in the through hole and including an active surface and an inactive surface, the active surface including a plurality of electrode pads;
forming at least one non photoimagable laminating layer on the first surface of the carrier board with a through hole to expose the inactive surface of the semiconductor chip;
forming a dielectric layer on the second surface of the carrier board and the active surface of the semiconductor chip; and
forming a circuit layer on the dielectric layer, the circuit layer electrically connecting to the electrode pads of the semiconductor chip through conductive structures in the dielectric layer.

2. The method of claim 1, further including forming a circuit build up structure on the surface of the dielectric layer and circuit layer.

3. The method of claim 2, wherein the circuit build up structure includes a dielectric layer, a circuit layer overlying on the surface of the dielectric layer and at least one conductive structure formed in the dielectric layer.

4. The method of claim 3, further including forming a plurality of electrically connecting pads on the outer surface of the circuit build up structure.

5. The method of claim 4, further including overlying an insulating protection layer on the outer surface of the circuit build up structure with a plurality of openings for exposing the electrically connecting pads on the outer surface of the circuit build up structure.

6. The method of claim 5, further including forming conductive elements on the electrically connecting pads.

7. The method of claim 1, wherein the carrier board is one of an insulating board, a metal board and a circuit board thereon.

8. The method of claim 2, wherein the number of the laminating layer increases with the circuit build up number of the circuit build up structure, so as to compensate warpage as a result of temperature variation during a circuit build up process.

9. The method of claim 1, wherein the carrier board includes at least two core plates and an interposed adhesive layer, the adhesive layer being filled into the gaps between the through hole of the carrier board and the semiconductor chip, so as to secure the semiconductor chip in the through hole.

10. The method of claim 1, wherein the core plates are at least one of an insulating plate, a metal plate and a circuit board thereon.

11. The method of claim 1, wherein the laminating layer is one of flow prepreg, non-flow prepreg, resin coated copper (RCC), Ajinomoto Build up Film, BCB (Benzocyclo-buthene), LCP (Liquid Crystal Polymer), PI (Poly-imide), PPE (Poly(phenylene ether)), PTFE (Poly(tetra-fluoroethylene)), FR4, FR5, BT (Bismaleimide Triazine) and Aramide.

12. A method for fabricating a circuit board structure with an embedded semiconductor chip, including:
providing a carrier board including a first and a second surface and at least one through hole penetrating the first and second surfaces;
forming at least one non photoimagable laminating layer on the first surface of the carrier board and forming a through hole in the laminating layer corresponding to the through hole of the carrier board;
disposing a semiconductor chip in the through hole and including an active surface and an inactive surface, the active surface including a plurality of electrode pads;
forming a dielectric layer on the second surface of the carrier board and the active surface of the semiconductor chip; and
forming a circuit layer on the dielectric layer, the circuit layer electrically connecting to the electrode pads of the semiconductor chip through conductive structures in the dielectric layer.

13. The method of claim 12, further including forming a circuit build up structure on the surface of the dielectric layer and circuit layer.

14. The method of claim 13, wherein the circuit build up structure includes a dielectric layer, a circuit layer overlying on the surface of the dielectric layer and at least one conductive structure formed in the dielectric layer.

15. The method of claim 14, further including forming a plurality of electrically connecting pads on the outer surface of the circuit build up structure.

16. The method of claim 15, wherein overlying an insulating protection layer on the outer surface of the circuit build up structure with a plurality of openings for exposing the electrically connecting pads on the outer surface of the circuit build up structure.

17. The method of claim 16, further including forming conductive elements on the electrically connecting pads.

18. The method of claim 13, wherein the carrier board is one of an insulating board, a metal board and a circuit board thereon.

19. The method of claim 12, wherein the number of the laminating layer increases with the circuit build up number of the circuit build up structure, so as to compensate warpage as a result of temperature variation during a circuit build up process.

20. The method of claim 12, wherein the carrier board includes at least two core plates and an interposed adhesive layer, the adhesive layer being filled into the gaps between the through hole of the carrier board and the semiconductor chip, so as to secure the semiconductor chip in the through hole.

21. The method of claim 20, wherein the core plates are at least one of an insulating plate, a metal plate and a circuit board thereon.

22. The method of claim 12, wherein the laminating layer is one of flow prepag, non-flow prepreg, resin coated copper (RCC), Ajinomoto Build up Film, BCB (Benzocyclo-buthene), LCP (Liquid Crystal Polymer), PI (Poly-imide), PPE (Poly(phenylene ether)), PTFE (Poly(tetra-fluoroethylene)), FR4, FR5, BT (Bismaleimide Triazine) and Aramide.
